(19) United States
(12) Patent Application Publication
(10) Pub. No.: US 2026/0142659 A1
(43) Pub. Date: May 21, 2026

(54) HIGH BANDWIDTH LEVEL-SHIFTING DIFFERENTIAL ANALOG INTERFACE CIRCUIT

(71) Applicant: Microchip Technology Incorporated, Chandler, AZ (US)

(72) Inventor: Michael Alan Baxter, Sunnyvale, CA (US)

(21) Appl. No.: 19/385,827

(22) Filed: Nov. 11, 2025

Related U.S. Application Data
(60) Provisional application No. 63/723,586, filed on Nov. 21, 2024.

(51) Int. Cl. H03K 19/018; H03K 19/00; H03K 19/013; H03K 19/0175

(52) U.S. Cl. CPC H03K 19/01812; H03K 19/0005; H03K 19/013; H03K 19/017581

(57) ABSTRACT

Disclosed herein are apparatus, system, method, and computer-readable medium aspects for interfacing a MIPI transmitter with a SERDES receiver. An example method aspect includes receiving first and second MIPI signals at respective inputs and level-shifting each signal using corresponding diodes. The level-shifted signals are applied to the base terminals of first and second transistors, whose emitters are coupled together. A control current is generated via a current mirror formed by a third and fourth transistor, with the current set by a control voltage. This control current is supplied to the coupled emitters, enabling the production of differential output signals at the collector terminals of the first and second transistors for input to a SERDES receiver.

### CROSS-REFERENCE TO RELATED APPLICATION

The present application claims priority from U.S. Provisional Patent Application No. 63/723,586, filed Nov. 21, 2024, which is incorporated herein by reference in its entirety.

### TECHNICAL FIELD

The present disclosure relates to generally to input/output (I/O) circuitry, and more specifically to high bandwidth level-shifting differential analog interface circuitry.

### SUMMARY

In one aspect, an interface circuit can include a first transistor and a second transistor, each having a base terminal, an emitter terminal, and a collector ter0minal. The emitter terminals of the first and second transistors can be coupled together. A first diode can have a cathode configured to be coupled to a first input and an anode coupled to the base terminal of the first transistor. Similarly, a second diode can have a cathode configured to be coupled to a second input and an anode coupled to the base terminal of the second transistor. A third transistor and a fourth transistor can be coupled together to form a current mirror. The collector terminal of the fourth transistor can be coupled to the emitter terminals of the first and second transistors, while the collector terminal of the third transistor can be coupled to a control voltage. The collector terminals of the first and second transistors can be configured to provide differential output signals.

In some aspects, the first and second transistors can be NPN bipolar junction transistors, and the third and fourth transistors can be NPN bipolar junction transistors. The current mirror can include a potentiometer and a resistor configured in series to set a control current, where the potentiometer can have a dynamic resistance range between 54.9Ω and 154.9Ω. The differential output signals can have a common-mode voltage of +800 mV and a differential signal swing of ±200 mV. Under high common-mode voltage conditions, the first and second diodes can be configured to switch off, allowing the first and second transistors to turn on and set the differential output signals to 0. The interface circuit can be implemented in surface-mount technology form or in through-hole form. Additionally, the circuit can be configured to operate with a 1.8 V power supply, and the control voltage can be obtained from a power supply having a positive voltage greater than the base-emitter voltage of the third transistor.

In another aspect, a method for interfacing a MIPI transmitter with a SERDES receiver can include receiving a first MIPI signal at a first input and a second MIPI signal at a second input. The method can further include level-shifting the first signal using a first diode and the second signal using a second diode, and applying the level-shifted signals to respective base terminals of a first transistor and a second transistor, where the emitters of the transistors are coupled together. A control current can be generated using a current mirror formed by a third transistor and a fourth transistor, with the control current set by a control voltage. This control current can be supplied to the coupled emitters of the first and second transistors, and differential output signals can be produced at the collector terminals of the first and second transistors for input to a SERDES receiver.

In some aspects of the method, the first and second transistors can be NPN bipolar junction transistors. The current mirror used to generate the control current can include a potentiometer and a resistor configured in series, with the potentiometer having a dynamic resistance range between 54.9Ω and 154.9Ω. The differential output signals can have a common-mode voltage of +800 mV and a differential signal swing of ±200 mV. During high common-mode voltage conditions, the first and second diodes can be configured to switch off, causing the first and second transistors to turn on and set the differential output signals to 0. The control voltage can be obtained from a 1.8 V power supply or from a power supply having a positive voltage greater than the base-emitter voltage of the third transistor.

In yet another aspect, an interface circuit can include a first transistor and a second transistor configured as a differential pair, and a current mirror comprising a third transistor and a fourth transistor. A collector terminal of the fourth transistor can be coupled to the emitters of the first and second transistors, while the collector terminal of the third transistor can be coupled to a control voltage. The collector terminals of the first and second transistors can be configured to provide differential output signals.

Further features and advantages, as well as the structure and operation of various aspects, are described in detail below with reference to the accompanying drawings. It is noted that the specific aspects described herein are not intended to be limiting. Such aspects are presented herein for illustrative purposes only. Additional aspects will be apparent to persons skilled in the relevant art(s) based on the teachings contained herein.

### BRIEF DESCRIPTION OF DRAWINGS

The accompanying drawings, which are incorporated herein and form a part of the specification, illustrate aspects of the present disclosure and, together with the description, further serve to explain the principles of the disclosure and to enable a person skilled in the pertinent art to make and use the disclosure

FIG. 1 shows a circuit diagram of an interface circuit, according to some aspects of the present disclosure.

FIG. 2 is a flowchart of a method for interfacing a MIPI transmitter with a SERDES receiver, according to some aspects of the present disclosure.

In the drawings, like reference numbers generally indicate identical or similar elements. Aspects of the present disclosure will be described with reference to the accompanying drawings.

### DETAILED DESCRIPTION OF VARIOUS EXAMPLES

Various electronic devices, such as digital cameras, use Mobile Industry Processor Interface (MIPI) specifications to interface with various processors or other devices, such as field programmable gate arrays (FPGAs). For example, digital cameras that may be used in medical or industrial applications may use a MIPI interface that is a fast serial interface called MIPI D-PHY. According to various examples, an FPGA may provide an interface for and buffering between a digital camera and a processor. However, general purpose input-output (GPIO) ports may not be capable of handling the maximum data rate of a MIPI interface, which may result in the use of a serializer-deserializer (SERDES). A SERDES may not be voltage compatible with direct current (DC) coupled MIPI interfaces due to voltage excursions used for switching speed/power modes in the MIPI standard, and so the SERDES receiver (RX) inputs may be unprotected against higher-voltage out-of-band (OOB) events which would otherwise be accepted at GPIO inputs. Another interoperability conflict with DC coupling is that the common mode voltage Vcm for MIPI may be different than that of the SERDES RX inputs.

Some SERDES may also not be alternating current (AC) compatible with MIPI interfaces, because the MIPI signals are not DC-balanced, like a typical SERDES line would be. Under AC-coupling conditions, MIPI non-return-to-zero (NRZ) differential signaling may cause line voltage drift due to charge accumulation across coupling capacitors. This can happen due to long runs of 1s or 0s on the line, which is possible with video information carried over MIPI. Therefore, a low-cost high-speed differential DC-coupled interface between a MIPI transmit (TX) port and a SERDES RX port is needed.

Accordingly, various examples may provide: (1) high-bandwidth to preserve the signal fidelity of 3.2 Gb/s MIPI TX NRZ data signals (“MIPI signals”) to a SERDES; (2) DC coupling, instead of AC-coupling, so that MIPI signals may not cause line drift, given potentially long runs of 1s or 0s in MIPI video data; (3) moderate gain of approximately 1.1-2.0×, so as to better match the signal swing of low voltage MIPI signals to that of a SERDES; and (4) DC level-shift so that electrical interoperability may be achieved with the SERDES RX port.

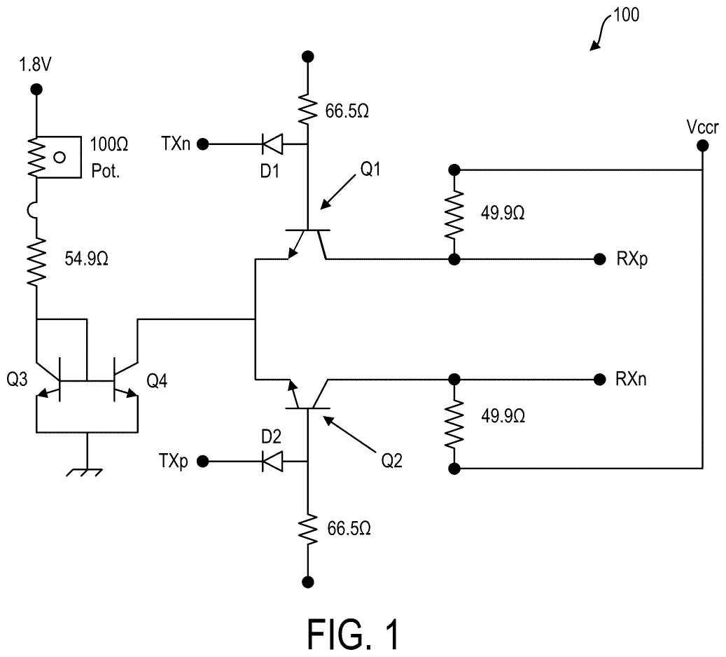

FIG. 1 shows an interface circuit 100 according to various examples. Referring to FIG. 1, the interface circuit may include first and second bipolar junction transistors (BJTs) Q1 and Q2, that may form an emitter-coupled differential pair that may operate as a transconductance gain stage. Both Q1 and Q2 can have a base terminal, an emitter terminal, and a collector terminal. First and second transistors Q1 and Q2 may act as a voltage controlled amplifier in the application, after a 1.8V “control voltage” is transformed into a current, as described below. The emitter terminals of Q1 and Q2 can be coupled together. A MIPI D-PHY TX output may drive a first input TXn (Q1) and a second input TXp (Q2), respectively through diodes D1 and D2, which may be silicon diodes each having a cathode coupled to respective inputs and an anode coupled to the base terminal of respective Q1 and Q2. A tail current of first and second transistors Q1 and Q2 may be driven by a current mirror formed by a third BJT Q3 and a fourth BJT Q4 coupled together.

The interface circuit 100 of FIG. 1 may operate based on a 1.8V power supply voltage, which may be the same power supply as an FPGA that may be coupled to the interface circuit. For illustration purposes without an FPGA present, an additional voltage reference supply Vccr is provided. The voltage Vccr stands in for a line termination (e.g. common-mode voltage) seen at the RX pins of a SERDES RX. In various applications, this voltage might already be present either from the system printed circuit board (PCB), or from the FPGA itself. BJTs Q1 through Q4 may be implemented with NPN silicon transistors, however other types of transistors may be used.

In operation, transistors Q1 through Q4 form a voltage-controlled amplifier with differential inputs and outputs. For example, the collector terminals of Q1 and Q2 can be configured to provide differential output signals. A collector terminal of Q3 is configured to be coupled to a control voltage. The control voltage is obtained via the +1.8V supply, but can be any positive voltage that is greater than the base-emitter voltage Vbe of the third transistor Q3. According to various examples, a 100Ω trim potentiometer in series with a 54.9Ω 1% resistor sets up a control current into the current mirror formed by the third and fourth transistors Q3 and Q4. The trimmer may allow a dynamic resistance range approximately between 54.9Ω and 154.9Ω. Given a nominal base-emitter voltage Vbe of ≈700 mv, and the 1.8V “control voltage” into the trimmer, the input current into the current mirror may range from approximately 7.1 mA to 20 mA. According to various examples, the third and fourth transistors Q3 and Q4 may have a current gain (β) of roughly 100, and about 98% of this input current may be reflected at a collector terminal of the fourth transistor Q4 to supply emitter current to the transconductance gain stage comprised of the emitter terminals of first and second transistors Q1 and Q2. Although a potentiometer is used in the example shown in FIG. 1, a single resistor may be use with any convenient power supply voltage. The gain range for the emitter currents indicated may be approximately less than 2.0.

According to various examples, the emitter current used may be set so as to allow differential output terminals RXp and RXn to have an effective input common mode voltage (Vicm) of +800 mV. A ±200 mV differential signal swing may be provided on the line when the TXn/TXp signal is provided, which may mate to a SERDES RX.

The diodes D1 and D2 may enable a level shift to match a level of low-level MIPI TXn/TXp signals, modulating the base terminals of the first and second transistors Q1 and Q2 to enable clean differential switching at the collector terminals of the first and second transistors Q1 and Q2. When the MIPI TX signals switch modes, differential operation may stop, and a higher common-mode voltage may appear across the TXn and TXp inputs. When this happens the diodes D1 and D2 may switch off, which causes first and second transistors Q1 and Q2 to be turned on, setting the differential outputs RXn and RXp to “0.” This action can also enable Loss Of Signal (LOS) detect by the SERDES RX, and it may electrically protect these inputs.

The interface circuit of FIG. 1 may be implemented in through-hole form that mimics at 1 MHz the action of the same circuit design implemented in surface-mount technology (SMT) form that might run at about 1562× higher frequency for 3.2 GBs MIPI. Aside from clean SMT layout on a PCB, this may use different, higher speed transistors for first and second transistors Q1 and Q2. Such devices may have a 46 GHz transition frequency. The third and fourth transistors Q3 and Q4 may be any NPN low-frequency SMT transistors. The diodes D1 and D2 may be a low-capacitance, high-frequency type, but this function may be represented by numerous available components.

The interface circuit of FIG. 1 can alternatively be implemented in SMT form. An at-frequency SMT version of the interface circuit of FIG. 1 may have additional necessary transmission line and controlled impedance PCB tracks. But this may be used for a SERDES application in any case. The interface circuit of FIG. 1, including diodes D1 and D2, and resistors, is relatively compact in PCB area, suitable for multiple MIPI D-PHY channels. According to various examples, the interface circuit may be implemented as an analog integrated circuit (IC) with a high-frequency bipolar process.

The interface circuit of FIG. 1 may accept a significant range, and possibly the entire range, of MIPI signal voltages, while also protecting the RX SERDES from over-voltage immunity under conditions when MIPI changes speed/power modes with higher DC voltage levels. The interface circuit of FIG. 1 may level shift the NRZ MIPI signals TXn and TXp interoperably with the RX SERDES DC levels, using a DC-coupled interface. The interface circuit of FIG. 1 may provide programmable gain which can be set on an application basis, using normally available voltages in a typical FPGA system.

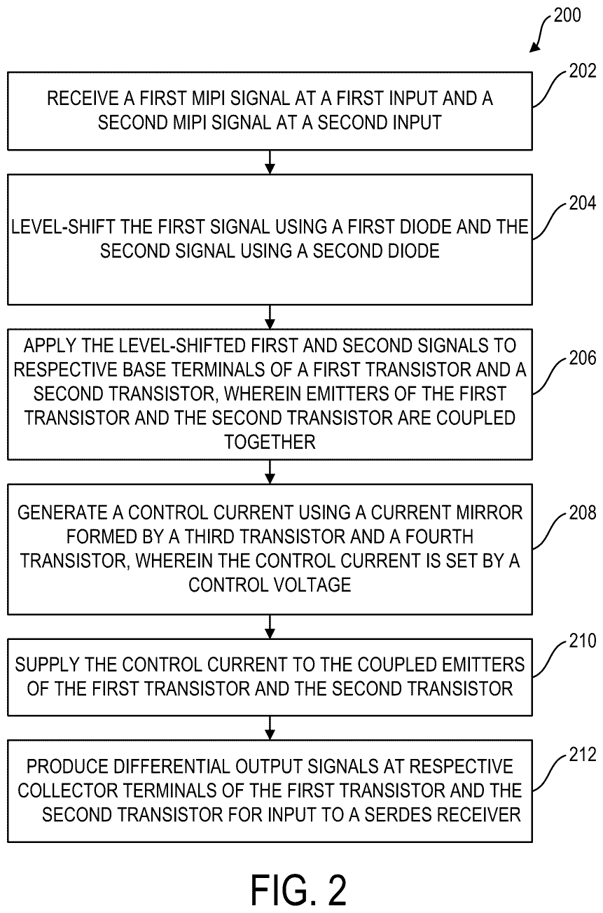

FIG. 2 is a flowchart for a method 200 for interfacing a MIPI transmitter with a SERDES receiver, according to one or more examples. It is to be appreciated that not all steps can be needed to perform the disclosure provided herein. Further, some of the steps can be performed simultaneously, or in a different order than shown in FIG. 2, as will be understood by a person of ordinary skill in the art. Method 200 can be implemented by interface circuit 100. However, method 200 is not limited to that example aspect.

In operation 202, a first MIPI signal is received at a first input and a second MIPI signal is received at a second input. In operation 204, the first signal is level-shifted using a first diode and the second signal is level-shifted using a second diode.

In operation 206, the level-shifted first and second signals are applied to respective base terminals of a first transistor and a second transistor. Emitters of the first transistor and the second transistor are coupled together. The first transistor and the second transistor can be NPN bipolar junction transistors.

In operation 208, a control current is generated using a current mirror formed by a third transistor and a fourth transistor. The control current is set by a control voltage. The current mirror can include a potentiometer and a resistor configured in series to generate the control current. The potentiometer can be configured with a dynamic resistance range between 54.9Ω and 154.9Ω. The control voltage can be obtained from a 1.8 V power supply. The control voltage can be obtained from a power supply having a positive voltage greater than a base-emitter voltage of the third transistor.

In operation 210, the control current is supplied to the coupled emitters of the first transistor and the second transistor. In operation 212, differential output signals are produced at respective collector terminals of the first transistor and the second transistor for input to a SERDES receiver. The differential output signals can have a common-mode voltage of +800 mV and a differential signal swing of ±200 mV. During a high common-mode voltage condition, the first diode and the second diode can be configured to switch off, such that the first transistor and the second transistor turn on and set the differential output signals to 0.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

Aspects have been described herein with the aid of functional building blocks illustrating the implementation of specified functions and relationships thereof. The boundaries of these functional building blocks have been arbitrarily defined herein for the convenience of the description. Alternate boundaries can be defined as long as the specified functions and relationships (or equivalents thereof) are appropriately performed. Also, alternative aspects can perform functional blocks, steps, operations, methods, etc. using orderings different than those described herein.

References herein to “one aspect,” “an aspect,” “an example aspect,” or similar phrases, indicate that the aspect described can include a particular feature, structure, or characteristic, but every aspect need not necessarily include the particular feature, structure, or characteristic. Moreover, such phrases are not necessarily referring to the same aspect. Further, when a particular feature, structure, or characteristic is described in connection with an aspect, it would be within the knowledge of persons skilled in the relevant art(s) to incorporate such feature, structure, or characteristic into other aspects whether or not explicitly mentioned or described herein. Additionally, some aspects can be described using the expression “coupled” and “connected” along with their derivatives. These terms are not necessarily intended as synonyms for each other. For example, some aspects can be described using the terms “connected” and/or “coupled” to indicate that two or more elements are in direct physical or electrical contact with each other. The term “coupled,” however, can also mean that two or more elements are not in direct contact with each other, but yet still co-operate or interact with each other.

The breadth and scope of this disclosure should not be limited by any of the above-described exemplary aspects, but should be defined only in accordance with the following claims and their equivalents.

What is claimed is:

1. An interface circuit, the interface circuit comprising:
a first transistor having a base terminal, an emitter terminal, and a collector terminal;
a second transistor having a base terminal, an emitter terminal, and a collector terminal, wherein the emitter terminal of the first transistor is coupled to the emitter terminal of the second transistor;
a first diode having a cathode configured to be coupled to a first input, and an anode coupled to the base terminal of the first transistor;
a second diode having a cathode configured to be coupled to a second input, and an anode coupled to the base terminal of the second transistor; and
a third transistor and a fourth transistor coupled together to form a current mirror; wherein a collector terminal of the fourth transistor is coupled to the emitter terminals of the first and second transistors, and wherein a collector terminal of the third transistor is coupled to a control voltage;
wherein the collector terminals of the first and second transistors are configured to provide differential output signals.

2. The interface circuit of claim 1, wherein the first transistor and the second transistor are NPN bipolar junction transistors.

3. The interface circuit of claim 1, wherein the third transistor and the fourth transistor are NPN bipolar junction transistors.

4. The interface circuit of claim 1, wherein the current mirror comprises a potentiometer and a resistor configured in series to set a control current.

5. The interface circuit of claim 4, wherein the potentiometer is configured with a dynamic resistance range between 54.9Ω and 154.9Ω.

6. The interface circuit of claim 1, wherein the differential output signals have a common-mode voltage of +800 mV and a differential signal swing of ±200 mV.

7. The interface circuit of claim 1, wherein the first diode and the second diode are configured to switch off during high common-mode voltage conditions such that the first transistor and the second transistor turn on and set the differential output signals to 0.

8. The interface circuit of claim 1, wherein the interface circuit is implemented in surface-mount technology form.

9. The interface circuit of claim 1, wherein the interface circuit is implemented in through-hole form.

10. The interface circuit of claim 1, wherein the interface circuit is configured to operate with a 1.8 V power supply.

11. The interface circuit of claim 1, wherein the control voltage is obtained from a power supply having a positive voltage greater than a base-emitter voltage of the third transistor.

12. A method for interfacing a MIPI transmitter with a SERDES receiver, comprising:
receiving a first MIPI signal at a first input and a second MIPI signal at a second input;
level-shifting the first signal using a first diode and the second signal using a second diode;
applying the level-shifted first and second signals to respective base terminals of a first transistor and a second transistor, wherein emitters of the first transistor and the second transistor are coupled together;
generating a control current using a current mirror formed by a third transistor and a fourth transistor, wherein the control current is set by a control voltage;
supplying the control current to the coupled emitters of the first transistor and the second transistor; and
producing differential output signals at respective collector terminals of the first transistor and the second transistor for input to a SERDES receiver.

13. The method of claim 12, wherein the first transistor and the second transistor are NPN bipolar junction transistors.

14. The method of claim 12, wherein the current mirror comprises a potentiometer and a resistor configured in series to generate the control current.

15. The method of claim 14, wherein the potentiometer is configured with a dynamic resistance range between 54.9Ω and 154.9Ω.

16. The method of claim 12, wherein the differential output signals have a common-mode voltage of +800 mV and a differential signal swing of ±200 m V.

17. The method of claim 12, wherein the first diode and the second diode are configured to switch off during high common-mode voltage conditions such that the first transistor and the second transistor turn on and set the differential output signals to 0.

18. The method of claim 12, wherein the control voltage is obtained from a 1.8 V power supply.

19. The method of claim 12, wherein the control voltage is obtained from a power supply having a positive voltage greater than a base-emitter voltage of the third transistor.

20. An interface circuit, the interface circuit comprising:
a first transistor and a second transistor configured as a differential pair; and
a current mirror comprising a third transistor and a fourth transistor,
wherein a collector terminal of the fourth transistor is coupled to emitters of the first transistor and the second transistor, wherein a collector terminal of the third transistor is coupled to a control voltage, and wherein collector terminals of the first transistor and the second transistor are configured to provide differential output signals.
